(19) United States
(12) Patent Application Publication
(10) Pub. No.: US 2026/0123182 A1
(43) Pub. Date: Apr. 30, 2026

(54) DISPLAY DEVICE, ELECTRONIC APPARATUS INCLUDING THE SAME AND METHOD OF MANUFACTURING DISPLAY DEVICE

(71) Applicant: Samsung Display Co., Ltd., Yongin-si (KR)

(72) Inventors: KYUNG-BAE KIM, Yongin-si (KR); Dongwan HA, Yongin-si (KR); GYUNGSOON PARK, Yongin-si (KR)

(21) Appl. No.: 19/351,103

(22) Filed: Oct. 6, 2025

(30) Foreign Application Priority Data
Oct. 24, 2024 (KR) 10-2024-0146891

(51) Int. Cl. H10K 59/121; H10K 59/12; H10K 59/131

(52) U.S. Cl. CPC H10K 59/1213; H10K 59/1201; H10K 59/131

(57) ABSTRACT

A display device includes: a semiconductor substrate; and a plurality of pixels in and on the semiconductor substrate, each of the plurality of pixels including: a light-emitting element; a first transistor between a first power line and the light-emitting element; and a second transistor between a data line and the first transistor. The first transistor includes a channel region, a source region adjacent to a first side of the channel region, a drain region adjacent to a second side of the channel region, and a gate on the channel region. The channel region of the first transistor includes a first channel region overlapping with the gate of the first transistor, and a second channel region not overlapping with the gate of the first transistor.

### CROSS-REFERENCE TO RELATED APPLICATION

The present application claims priority to and the benefit of Korean Patent Application No. 10-2024-0146891, filed on October 24, 2024, in the Korean Intellectual Property Office, the entire disclosure of which is incorporated by reference herein.

### BACKGROUND

Aspects of embodiments of the present disclosure relate to a display device including a semiconductor substrate, an electronic apparatus including the display device, and a method of manufacturing the display device.

An electronic apparatus, such as a smartphone, a laptop computer, a navigation device, and a smart television, provides an image to a user and may include a display device for displaying the image. An augmented reality apparatus, a virtual reality apparatus, or a video projection apparatus may include a micro display device. The micro display device may include a silicon wafer, and a light-emitting element disposed on the silicon wafer, so as to be driven with a low power and display a high-luminance image.

The above information disclosed in this Background section is for enhancement of understanding of the background of the present disclosure, and therefore, it may contain information that does not constitute prior art.

### SUMMARY

Embodiments of the present disclosure may be directed to a display device including a semiconductor substrate, an electronic apparatus including the display device, and a method of manufacturing the display device.

According to one or more embodiments of the present disclosure, a display device includes: a semiconductor substrate; and a plurality of pixels in and on the semiconductor substrate, each of the plurality of pixels including: a light-emitting element; a first transistor between a first power line and the light-emitting element; and a second transistor between a data line and the first transistor. The first transistor includes a channel region, a source region adjacent to a first side of the channel region, a drain region adjacent to a second side of the channel region, and a gate on the channel region. The channel region of the first transistor includes a first channel region overlapping with the gate of the first transistor, and a second channel region not overlapping with the gate of the first transistor.

In an embodiment, the first transistor may include a PMOS transistor.

In an embodiment, the source region of the first transistor may be electrically connected to the first power line.

In an embodiment, the first transistor may include an NMOS transistor.

In an embodiment, the source region of the first transistor may be electrically connected to the light-emitting element.

In an embodiment, at least a portion of the semiconductor substrate may be doped with a first impurity, and the source region of the first transistor and the drain region of the first transistor may be doped with a second impurity different from the first impurity.

In an embodiment, the gate and the source region of the first transistor may be spaced from each other in a plan view, and the gate and the drain region of the first transistor may be adjacent to each other in a plan view.

In an embodiment, the second transistor may include a channel region, a source region adjacent to a first side of the channel region, a drain region adjacent to a second side of the channel region, and a gate on the channel region. The channel region of the second transistor may entirely overlap with the gate of the second transistor.

In an embodiment, the gate and the source region of the second transistor may be adjacent to each other in a plan view, and the gate and the drain region of the second transistor may be adjacent to each other in a plan view.

In an embodiment, a first source length and a first drain length of the first transistor may be different from each other, and a second source length and a second drain length of the second transistor may be same as each other.

In an embodiment, a length of the gate of the first transistor may be greater than a length of the gate of the second transistor.

In an embodiment, the second channel region may have a higher resistance than that of the first channel region.

According to one or more embodiments of the present disclosure, a method of manufacturing a display device includes: preparing a preliminary semiconductor substrate doped with a first impurity; providing a semiconductor substrate by forming a source region and a drain region by doping first and second doped regions of the preliminary semiconductor substrate with a second impurity by using a first mask; forming a preliminary gate insulating layer on an upper surface of the semiconductor substrate; forming a preliminary gate on an upper surface of the preliminary gate insulating layer; and forming a gate insulating layer and a gate by etching the preliminary gate insulating layer and the preliminary gate by using a second mask. The display device includes a first channel region overlapping with the gate in a plan view, and a second channel region not overlapping with the gate in a plan view between the source region and the drain region.

In an embodiment, the display device may include a plurality of pixels disposed in and on the semiconductor substrate, each of the plurality of pixels including: a light-emitting element; a first transistor disposed between a first power line and the light-emitting element; and a second transistor disposed between a data line and the first transistor. The first transistor may include the source region, the drain region, and the gate.

In an embodiment, the gate and the source region of the first transistor may be spaced apart from each other in a plan view, and the gate and the drain region of the first transistor may be adjacent to each other in a plan view.

In an embodiment, the first mask may not overlap with the source region and the drain region of the first transistor.

In an embodiment, the second mask may overlap with the gate insulating layer and the gate of the first transistor.

In an embodiment, the first mask may overlap with the second channel region, and the second mask may not overlap with the second channel region.

In an embodiment, the second channel region may have a higher resistance than that of the first channel region.

According to one or more embodiments of the present disclosure, an electronic apparatus includes: a display panel; a frame accommodating the display panel; and a structure on which the frame is mounted. The display panel includes: a semiconductor substrate; and a plurality of pixels in and on the semiconductor substrate. Each of the plurality of pixels includes: a light-emitting element; a first transistor between a first power line and the light-emitting element; and a second transistor between a data line and the first transistor. The first transistor includes a channel region, a source region adjacent to a first side of the channel region, a drain region adjacent to a second side of the channel region, and a gate on the channel region. The channel region of the first transistor includes a first channel region overlapping with the gate of the first transistor, and a second channel region not overlapping with the gate of the first transistor.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of a display device according to an embodiment of the present disclosure;

FIG. 2 is a cross-sectional view of a display device according to an embodiment of the present disclosure;

FIG. 3A is a plan view of a unit region according to an embodiment of the present disclosure;

FIG. 3B is a cross-sectional view corresponding to one light-emitting region among a first light-emitting region, a second light-emitting region, and a third light-emitting region of FIG. 3A;

FIG. 4 is a block diagram of a display device according to an embodiment of the present disclosure;

FIG. 5A is a circuit diagram of a pixel according to an embodiment of the present disclosure;

FIG. 5B is a circuit diagram of a pixel according to an embodiment of the present disclosure;

FIG. 5C is a circuit diagram of a pixel according to an embodiment of the present disclosure;

FIG. 6 is a block diagram of a first transistor according to an embodiment of the present disclosure;

FIG. 7 is a block diagram of a second transistor according to an embodiment of the present disclosure;

FIG. 8 is a plan view of a first transistor according to an embodiment of the present disclosure;

FIG. 9 is a plan view of a second transistor according to an embodiment of the present disclosure;

FIGS. 10A-10F are cross-sectional views illustrating a method of manufacturing a first transistor according to an embodiment of the present disclosure;

FIG. 11 is a block diagram of an electronic apparatus according to an embodiment of the present disclosure; and

FIG. 12 is an exploded perspective view of an electronic apparatus according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

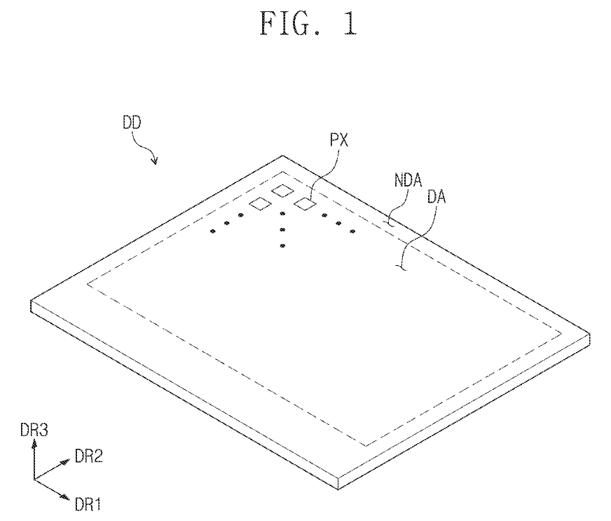

FIG. 1 is a perspective view of a display device according to an embodiment of the present disclosure.

Referring to FIG. 1, a display device DD may have a rectangular shape including a long side parallel to or substantially parallel to a first direction DR1, and a short side parallel to or substantially parallel to a second direction DR2 crossing the first direction DR1. However, the present disclosure is not limited thereto, and the display device DD may have various suitable shapes, such as a circular shape or a polygonal shape. Hereinafter, a direction perpendicularly or substantially perpendicularly crossing a plane defined by the first direction DR1 and the second direction DR2 is defined as a third direction DR3. As used herein, the phrase “in a plan view” is defined as a state of being viewed in/from the third direction DR3.

The display device DD according to an embodiment may be activated in response to an electrical signal. The display device DD may be a display included in a television, a monitor, an outdoor billboard, a tablet PC, a car navigation unit or device, a personal computer, a laptop computer, a personal digital terminal, a game console, a smartphone, a camera, and/or a wearable apparatus. For example, the wearable apparatus may include a virtual reality apparatus, an augmented reality apparatus, a smart watch, and the like. The virtual reality apparatus and the augmented reality apparatus may be an apparatus in the form of glasses wearable for a user. However, the present disclosure is not limited to the examples of the apparatuses described above, and according to embodiments of the present disclosure, the display device DD may display an image through a display region DA. A non-display region NDA may surround (e.g., around a periphery of) the display region DA. Unlike that illustrated in FIG. 1, the non-display region NDA may be disposed to be adjacent to one side (e.g., only one side) of the display region DA, or may be omitted as needed or desired.

A plurality of pixels PX may be disposed in the display region DA. The pixels PX may be arranged in a matrix form. The pixels PX may each include a pixel circuit and a light-emitting diode. The pixels PX may generate light of the same color as each other. As another example, a plurality of pixels PX that generate light of different colors from each other, for example, such as first pixels that output a first color light (e.g., red light), second pixels that output a second color light (e.g., green light), and third pixels that output a third color light (e.g., blue light), may be disposed in the display region DA.

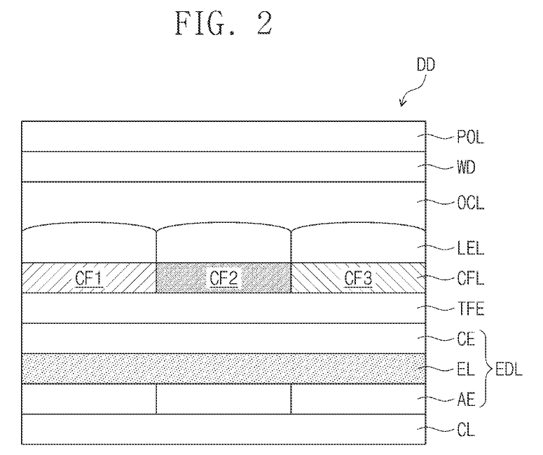

FIG. 2 is a cross-sectional view of a display device according to an embodiment of the present disclosure.

Referring to FIG. 2, a display device DD may include a circuit layer CL, a light-emitting element layer EDL, a thin-film encapsulation layer TFE, a color filter layer CFL, a lens layer LEL, an overcoat layer OCL, a window WD, and a polarizing layer POL.

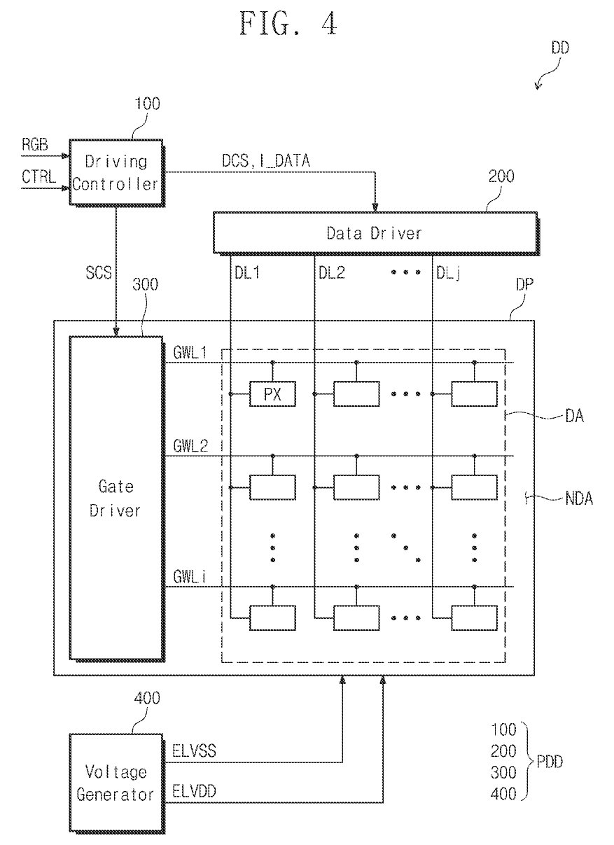

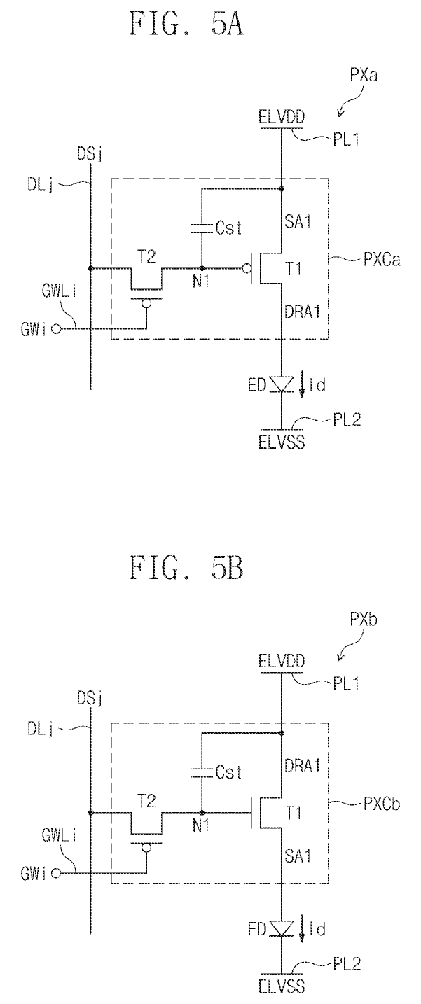

Transistors constituting a data driver 200 (e.g., see FIG. 4), a gate driver 300 (e.g., see FIG. 4), a pixel circuit PXCa (e.g., see FIG. 5A), and the like may be formed in the circuit layer CL. The circuit layer CL may include at least one insulating layer, a semiconductor pattern, a conductive pattern, a signal line, and the like. An insulating layer, a semiconductor layer, and a conductive layer may be formed by coating, deposition, or the like, and thereafter, the insulating layer, the semiconductor layer, and the conductive layer may be selectively patterned through multiple photolithography process. As a result, the semiconductor pattern, the conductive pattern, and the signal line included in the circuit layer CL may be formed.

The light-emitting element layer EDL may be disposed on the circuit layer CL. The light-emitting element layer EDL may include a first electrode AE, an emission layer EL, and a second electrode CE. In the present embodiment, the first electrode AE may be an anode, and the second electrode CE may be a cathode.

The first electrode AE may include a transparent conductive oxide pattern. The first electrode AE may be separately formed in each of the pixels PX. The transparent conductive oxide pattern may include indium tin oxide (ITO), indium zinc oxide (IZO), indium gallium zinc oxide (IGZO), zinc oxide (ZnOx), indium oxide (In2O3), or aluminum-doped zinc oxide (AZO), which facilitates hole injection. The first electrode AE may have a single-layer or multi-layered structure.

The emission layer EL may be disposed on the first electrode AE. The emission layer EL may have an integrated shape, and may be provided in common to the pixels PX. In a case in which the emission layer EL has the integrated shape, the emission layer EL may provide blue light or white light. However, the present disclosure is not limited thereto, and the emission layer EL may be separately formed in each of the pixels PX. In a case in which the emission layer EL is separately formed in each of the pixels PX, each emission layer EL may emit at least one of a first color light, a second color light, or a third color light. The emission layer EL may include an organic light-emitting material, quantum dots, quantum rods, a micro-LED, or a nano-LED.

The second electrode CE may be disposed on the emission layer EL. The second electrode CE may have an integrated shape, and may be disposed in common in a plurality of pixels PX. A common voltage may be provided to the second electrode CE, and the second electrode CE may be referred to as a common electrode.

The thin-film encapsulation layer TFE may be disposed on the light-emitting element layer EDL. The thin-film encapsulation layer TFE may protect the light-emitting element layer EDL from moisture, oxygen, and foreign substances, such as dust particles. The encapsulation layer TFE may include at least one inorganic film (hereinafter, an inorganic encapsulation film). In addition, the encapsulation layer TFE may further include at least one organic film (hereinafter, an organic encapsulation film). The thin-film encapsulation layer TFE may include an inorganic encapsulation layer, an organic encapsulation layer, and an inorganic encapsulation layer, which are sequentially stacked, but the layers constituting the thin-film encapsulation layer TFE are not limited thereto.

The color filter layer CFL may be disposed on the thin-film encapsulation layer TFE. The color filter layer CFL may include a plurality of color filters CF1, CF2 and CF3. The plurality of color filters CF1, CF2, and CF3 may include a first color filter CF1, a second color filter CF2, and a third color filter CF3. The first color filter CF1 may convert a color of light (e.g., blue light) that is generated in the emission layer EL into a first color light, and may output the first color light. The second color filter CF2 may convert a color of light that is generated in the emission layer EL into a second color light, and may output the second color light. The third color filter CF3 may not convert a color of light, but may transmit the color of light that is generated in the emission layer EL, and may output the color of light as a third color light. In some embodiments, the color filter layer CFL may further include a light blocking pattern.

The lens layer LEL may be disposed on the color filter layer CFL. The lens layer LEL may include a plurality of lens patterns. The lens patterns may be disposed in correspondence with the first to third color filters CF1, CF2, and CF3, respectively, and may be spaced apart from each other.

The overcoat layer OCL may be disposed on the lens layer LEL. The overcoat layer OCL may be optically transparent. As a planarization layer, the overcoat layer may include a flat or substantially flat upper surface.

The window WD may be disposed on the overcoat layer OCL. The window WD provides an outer surface of the display device DD.

The polarizing layer POL may be disposed on the window WD. The polarizing layer POL may block external light incident from the outside onto the display device DD. The polarizing layer POL may block a part of the external light. In addition, the polarizing layer POL may reduce reflected light, which may be generated at a display panel DP (e.g., see FIG. 4) by the external light. In other words, the polarizing layer POL may be an anti-reflective layer. For example, the polarizing layer POL may function to block reflected light in a case in which light incident from outside the display device DD is incident onto the display panel DP (e.g., see FIG. 4) and exits back.

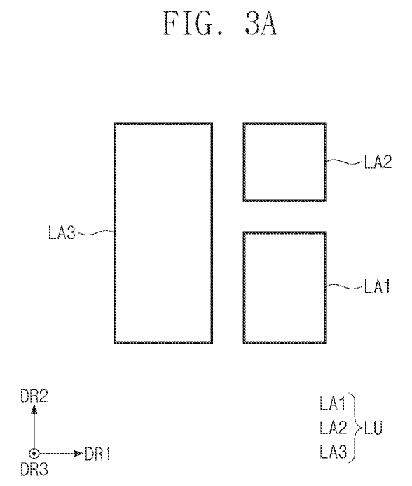

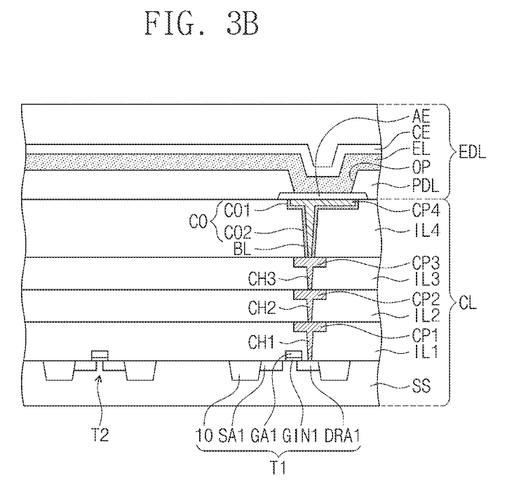

FIG. 3A is a plan view of a unit region according to an embodiment of the present disclosure.

FIG. 3A illustrates a unit region LU that may be repeatedly disposed in the display region DA of FIG. 1. The unit region LU may include a first light-emitting region LA1, a second light-emitting region LA2, and a third light-emitting region LA3. A first light-emitting element of a first pixel, a second light-emitting element of a second pixel, and a third light-emitting element of a third pixel may be respectively disposed in the first light-emitting region LA1, the second light-emitting region LA2, and the third light-emitting region LA3.

A first color light, a second color light, and a third color light may be output through the first light-emitting region LA1, the second light-emitting region LA2, and the third light-emitting region LA3, respectively. The first light-emitting element, the second light-emitting element, and the third light-emitting element may generate the same color light as each other (e.g., blue light) from the emission layer EL (e.g., see FIG. 2), which may be integrally formed. The color filters respectively disposed in the first light-emitting region LA1, the second light-emitting region LA2, and the third light-emitting region LA3 may convert the color light that is generated from the emission layer EL (e.g., see FIG. 2), which may be integrally formed, into the first color light, the second color light, and the third color light, or may transmit the color light that is generated from the emission layer EL, which may be integrally formed. In an embodiment of the present disclosure, light-emitting elements that generate light of different colors from each other may be disposed in the first light-emitting region LA1, the second light-emitting region LA2, and the third light-emitting region LA3, respectively.

Red light may be output through the first light-emitting region LA1, green light may be output through the second light-emitting region LA2, and blue light may be output through the third light-emitting region LA3. The arrangement of the first light-emitting region LA1, the second light-emitting region LA2, and the third light-emitting region LA3, an area ratio of the first light-emitting region LA1, the second light-emitting region LA2, and the third light-emitting region LA3, and a shape of the first light-emitting region LA1, the second light-emitting region LA2, and the third light-emitting region LA3, which are illustrated in FIG. 3A, are provided as an example, and the present disclosure is not limited thereto.

FIG. 3B is a cross-sectional view corresponding to one light-emitting region among the first light-emitting region, the second light-emitting region, and the third light-emitting region of FIG. 3A.

FIG. 3B illustrates, in more detail, the circuit layer CL and the light-emitting element layer EDL of the cross section of the display device DD illustrated in FIG. 2. The components included in the light-emitting element layer EDL illustrated in FIG. 3B may be the same or substantially the same as (or similar to) the components included in the light-emitting element layer EDL described above with reference to FIG. 2, and thus, are denoted with the same reference numerals or symbols. Accordingly, redundant description thereof may not be repeated.

The circuit layer CL may include a semiconductor substrate SS, at least one insulating layer IL1 to IL4, and at least one conductive pattern CP1 to CP4. In the present embodiment, the circuit layer CL including four insulating layers IL1 to IL4 and four conductive patterns CP1 to CP4 is illustrated as an example.

The semiconductor substrate SS may be a silicon substrate, a germanium substrate, or a silicon-germanium substrate. A plurality of pixels PX (e.g., see FIG. 4) May be formed in and on the semiconductor substrate SS. The semiconductor substrate SS may include a source region SA1 and a drain region DRA1. The source region SA1 and the drain region DRA1 may each be a region that is doped with an impurity. A pair of the source regionSA1 and the drain region DRA1 may define a transistor with a gate GA1 described in more detail below. The source region SA1 and the drain region DRA1 may be a source of a transistor or a drain of a transistor according to a signal flow. Shallow trench isolation (STI) regions 10 may be further defined in the semiconductor substrate SS. The STI regions 10 may prevent or substantially prevent a leakage current by isolating a transistor. The STI regions 10 may be disposed differently according to a design of a pixel circuit.

A gate insulating layer GIN1 and the gate GA1 are disposed on the semiconductor substrate SS. The gates GA1 may include a metal. Each of the gates GA1 is disposed in correspondence to a pair of the source region SA1 and the drain region DRA1. The gate insulating layer GIN1 may include insulating patterns disposed in correspondence to the gates GA1.

A first insulating layer IL1 may be disposed on the semiconductor substrate SS. The first insulating layer IL1 may overlap with a plurality of pixels in common, and may cover the gates GA1 of transistors T1 and T2. The first insulating layer IL1 may be an inorganic layer and/or an organic layer, and may have a single-layer or multi-layered structure. The first insulating layer IL1 may include at least one of aluminum oxide, titanium oxide, silicon oxide, silicon nitride, silicon oxynitride, zirconium oxide, or hafnium oxide. In the present embodiment, the first insulating layer IL1 may be a single-layer silicon oxide layer. Not only the first insulating layer IL1, but also second to fourth insulating layers IL2 to IL4 to be described in more detail below, may be an inorganic layer and/or an organic layer, and may have a single-layer or multi-layered structure. The inorganic layer may include at least one of the inorganic materials described above, but the present disclosure is not limited thereto.

Contact holes CH1, CH2, CH3 and CO are defined in the insulating layers IL1 to IL4. An uppermost insulating layer among the insulating layers IL1 to IL4 is defined as the fourth insulating layer IL4, and an opening formed in the fourth insulating layer IL4 is defined as a contact opening CO.

The second insulating layer IL2 may be disposed on the first insulating layer IL1 and may overlap with the pixels in common. The second insulating layer IL2 may be an inorganic layer and/or an organic layer and may have a single-layer or multi-layered structure. In the present embodiment, the second insulating layer IL2 may be a single-layer silicon oxide layer. The second conductive pattern CP2 may be disposed in the second insulating layer IL2. The second conductive pattern CP2 may be connected to the first conductive pattern CP1 through a second contact hole CH2.

A first conductive pattern CP1 may be disposed in the first insulating layer IL1. The first conductive pattern CP1 may be connected to the source region SA1 and/or the drain region DRA1 of the transistors T1 and T2 through a first contact hole CH1. In the present embodiment, the first conductive pattern CP1 is illustrated as being connected to the drain region DRA1 of a first transistor T1. Not only the first conductive pattern CP1, but also second to fourth conductive patterns CP2, CP3, and CP4 to be described in more detail below, may be defined as a contact electrode. Upper surfaces of the conductive patterns CP1 to CP4 may define the same or substantially the same flat surfaces (e.g., surfaces that are continuous with the upper surfaces of the insulating layers IL1 to IL4) as those of upper surfaces of the insulating layers IL1 to IL4. The conductive patterns CP1 to CP4 may be formed through a chemical/physical polishing process, for example, such as a damascene process. A material of the conductive patterns CP1 to CP4 is not particularly limited, as long as the material has a high conductivity and a high reflectance. For example, the conductive patterns CP1 to CP4 may include any one of copper (Cu), aluminum (Al), tungsten (W), molybdenum (Mo), chromium (Cr), gold (Au), titanium (Ti), nickel (Ni), neodymium (Nd), or a suitable alloy including at least one thereof.

The third insulating layer IL3 may be disposed on the second insulating layer IL2, and may overlap with the pixels in common. The third insulating layer IL3 may be an inorganic layer and/or an organic layer, and have a single-layer or multi-layered structure. In the present embodiment, the third insulating layer IL3 may be a single-layer silicon oxide layer. The third conductive pattern CP3 may be disposed in the third insulating layer IL3. The third conductive pattern CP3 may be connected to the second conductive pattern CP2 through a third contact hole CH3.

The fourth insulating layer IL4 may be disposed on the third insulating layer IL3, and may overlap with the pixels in common. The fourth insulating layer IL4 may be an inorganic layer and/or an organic layer, and may have a single-layer or multi-layered structure. In the present embodiment, the fourth insulating layer IL4 may be a single-layer silicon oxide layer. The fourth conductive pattern CP4 may be disposed in the fourth insulating layer IL4. The fourth conductive pattern CP4 may be connected to the third conductive pattern CP3 through the contact opening CO.

The contact opening CO formed in the fourth insulating layer IL4 may be divided into two regions. The contact opening CO may include a first region CO1 having a relatively greater width, and a second region CO2 continuous from the first region CO1, disposed below the first region CO1, and having a relatively smaller width. A width of the first region CO1 is not necessarily limited to being constant in a thickness direction, and a width of the second region CO2 is not necessarily limited to being constant in the thickness direction. A variation in width between the first region CO1 and the second region CO2 may be greater than a variation in width in the first region CO1 or a variation in width in the second region CO2.

A conductive pattern is disposed in the contact opening CO. The conductive pattern may be defined as the fourth conductive pattern CP4. The fourth conductive pattern CP4 may have the same or substantially the same shape as that of the contact opening CO. A width (or an area in a plan view) of a portion disposed in the first region CO1 is greater, and a width (or an area in a plan view) of a portion disposed in the second region CO2 is smaller.

In the present embodiment, the contact opening CO is illustrated as being formed in one insulating layer IL4, but the present disclosure is not limited thereto. In an embodiment of the present disclosure, the contact opening CO may be formed in two or more insulating layers.

A barrier layer BL may be further disposed on an inner surface, which defines the contact opening CO, of the fourth insulating layer IL4. In other words, the barrier layer BL may be further disposed between the fourth conductive pattern CP4 and the inner surface of the fourth insulating layer IL4. The barrier layer BL may not be disposed on an upper surface of the fourth insulating layer IL4.

The barrier layer BL may include a barrier metal layer and/or a nitride layer of a barrier metal. The barrier metal layer may be directly disposed on the inner surface of the fourth insulating layer IL4, and the nitride layer of a barrier metal may be disposed on the barrier metal layer.

The barrier metal layer improves a bonding force of the fourth conductive pattern CP4, and the nitride layer of a barrier metal prevents or substantially prevents diffusion of atoms of the fourth conductive pattern CP4. The barrier metal layer may include titanium or tantalum. The nitride layer of a barrier metal may include a titanium nitride layer or a tantalum nitride layer. For example, the barrier layer BL may include a titanium layer, and a titanium nitride layer disposed on the titanium layer. In addition, the barrier layer BL may include a tantalum layer, and a tantalum nitride layer disposed on the tantalum layer.

The fourth conductive pattern CP4 electrically connects the third conductive pattern CP3 below the fourth conductive pattern CP4 and a first electrode AE above the fourth conductive pattern CP4 to each other. In addition, the fourth conductive pattern CP4 serves as a reflective layer of a light-emitting element. A resonance phenomenon may be used in the light-emitting element to increase light emission efficiency of light generated in a light-emitting unit. Two reflective layers are disposed on both sides (e.g., opposite sides) of the light-emitting unit to generate the resonance phenomenon. Among the both sides (e.g., opposite sides) of the light-emitting unit, a translucent reflective layer may be disposed on a side through which light passes, and an opaque reflective layer having a high reflectance may be disposed on the opposite side. The fourth conductive pattern CP4 may serve as an opaque reflective layer.

The light-emitting element layer EDL may be disposed on the fourth insulating layer IL4. The light-emitting element layer EDL illustrated in FIG. 3B may further include a pixel-defining film PDL in the light-emitting element layer EDL illustrated in FIG. 2. The pixel-defining film PDL may be an organic layer. In the present embodiment, a single-layer pixel-defining film PDL is illustrated as an example, but the present disclosure is not limited thereto. An opening OP that partially exposes the first electrode AE is defined in the pixel-defining film PDL.

The opening OP substantially defines a corresponding light-emitting region among the light-emitting regions LA1, LA2, and LA3 of FIG. 3A. The opening OP is disposed in the fourth conductive pattern CP4 in a plan view to align a light-emitting region of an emission layer EL and a reflective region of the fourth conductive pattern CP4 with each other. Light generated in the light-emitting regions LA1, LA2, and LA3 may be sufficiently reflected at the fourth conductive pattern CP4 having a greater area. A width of the opening OP may be smaller than a width of the fourth conductive pattern CP4.

FIG. 4 is a block diagram of a display device according to an embodiment of the present disclosure.

Referring to FIG. 4, a display device DD may include a display panel DP and a panel driver PDD. As an example, the panel driver PDD may include a driving controller 100, a data driver 200, a gate driver 300, and a voltage generator 400.

The display panel DP may include a display region DA, and a non-display region NDA surrounding (e.g., around a periphery of) at least a portion of the display region DA. The display panel DP may include a plurality of pixels PX disposed in the display region DA. The display panel DP may include write scan lines GWL1 to GWLi and data lines DL1 to DLj, where i and j may be integers (or natural numbers) equal to or greater than 1.

The driving controller 100 receives an image signal RGB and a control signal CTRL. The driving controller 100 generates image data I_DATA obtained by converting a data format of the image signal RGB to comply with specifications of an interface with the data driver 200. The driving controller 100 outputs a first driving control signal SCS and a second driving control signal DCS.

The data driver 200 receives the second driving control signal DCS and the image data I_DATA from the driving controller 100. The data driver 200 converts the image data I_DATA into data signals, and outputs the data signals to the data lines DL1 to DLj. The data signals may be analog voltages corresponding to a grayscale value of the image data I_DATA.

The gate driver 300 may be disposed in the non-display region NDA of the display panel DP. The gate driver 300 receives the first driving control signal SCS from the driving controller 100. The gate driver 300 may be connected to the write scan lines GWL1 to GWLi. The gate driver 300 may output write scan signals to the write scan lines GWL1 to GWLi in response to the first driving control signal SCS.

The voltage generator 400 (e.g., a power supply part) generates voltages used for an operation of the display panel DP. In the present embodiment, the voltage generator 400 may generate a first driving voltage ELVDD and a second driving voltage ELVSS.

The plurality of pixels PX may each include a light-emitting element ED, and a pixel circuit PXCa (e.g., see FIG. 5A) to control a light emission of the light-emitting element ED. The pixel circuit PXCa may include at least one transistor and at least one capacitor. The gate driver 300 may include transistors formed through the same or substantially the same process as that for the pixel circuit PXCa (e.g., see FIG. 5A).

The plurality of pixels PX may be electrically connected to the write scan lines GWL1 to GWLi and the data lines DL1 to DLj. For example, pixels of an i-th row may be connected to i-th write scan lines GWLi, and pixels of a j-th column may be connected to a j-th data line DLj. However, the present disclosure is not limited thereto, and the plurality of pixels PX may each be connected to more than one scan line.

The plurality of pixels PX may each be connected to a first power line and a second power line. The first power line receives the first driving voltage ELVDD from the voltage generator 400, and the second power line receives the second driving voltage ELVSS from the voltage generator 400. However, the present disclosure is not limited thereto, and the plurality of pixels PX may each receive an initialization voltage and/or a reference voltage.

FIG. 5A is a circuit diagram of a pixel according to an embodiment of the present disclosure. FIG. 5B is a circuit diagram of a pixel according to an embodiment of the present disclosure.

FIG. 5A illustrates a pixel PXa including a pixel circuit PXCa, and a light-emitting element ED electrically connected to the pixel circuit PXCa as an example. FIG. 5B illustrates a pixel PXb including a pixel circuit PXCb, and a light-emitting element ED electrically connected to the pixel circuit PXCb as an example. Because the pixel circuit PXCa of FIG. 5A and the pixel circuit PXCb of FIG. 5B include similar components as each other, except that first transistors T1 thereof are a P-type transistor (e.g., PMOS) and an N-type transistor (e.g., NMOS), respectively, the pixel PXa of FIG. 5A may be described in more detail hereinafter, and redundant description with respect to the pixel PXb of FIG. 5B may not be repeated.

In an embodiment, referring to FIG. 5A, the pixel circuit PXCa may include two transistors (e.g., first and second transistors T1 and T2) and one capacitor Cst. The first transistor T1 and the second transistor T2 may each be a transistor having a low-temperature polycrystalline silicon (LTPS) semiconductor layer. As an example, the first and second transistors T1 and T2 may be P-type transistors.

The pixel PXa may be connected to the i-th write scan line GWLi among the plurality of write scan lines GWL1 to GWLi, and may be connected to the j-th data line DLj among the plurality of data lines DL1 to DLj (e.g., see FIG. 4). The i-th write scan line GWLi may transmit an i-th write scan signal GWi to the pixel PXa, and the j-th data line DLj may transmit a j-th data signal DSj to the pixel PXa. The j-th data signal DSj may have a voltage level corresponding to a grayscale value of the image data I_DATA output from the driving controller 100 (e.g., see FIG. 4).

The pixel PXa may be connected to a first power line PL1 that receives a first driving voltage ELVDD, and a second power line PL2 that receives a second driving voltage ELVSS. The first driving voltage ELVDD may have a higher voltage level than that of the second driving voltage ELVSS.

The light-emitting element ED may include an anode and a cathode. In a case in which the light-emitting element ED is an organic light-emitting element, the light-emitting element ED may further include an organic layer disposed between the anode and the cathode. The anode of the light-emitting element ED may be connected to the pixel circuit PXCa. The cathode of the light-emitting element ED may be connected to the second power line PL2. The light-emitting element ED may emit light in correspondence to an amount of current flowing through the first transistor T1 of the pixel circuit PXCa.

The first transistor T1 is connected between the anode of the light-emitting element ED and the first power line PL1 that receives the first driving voltage ELVDD. The first transistor T1 may be referred to as a driving transistor. The first transistor T1 may include a first electrode, a second electrode, and a gate electrode. The gate electrode may be connected to a first node N1, the first electrode may be electrically connected to the first power line PL1, and the second electrode may be connected to the anode of the light-emitting element ED. The first electrode may be referred to as a source region SA1 of the first transistor T1, and the second electrode may be referred to as a drain region DRA1 of the first transistor T1. According to a switching operation of the second transistor T2, the first transistor T1 may receive the j-th data signal DSj transmitted by the j-th data line DLj, and may supply a driving current Id to the light-emitting element ED.

FIG. 5A illustrates a case in which the first transistor T1 is a P-type transistor, and thus, the source region SA1 of the first transistor T1 is electrically connected to the first power line PL1, and the drain region DRA1 of the first transistor T1 is electrically connected to the anode of the light-emitting element ED. However, as illustrated in FIG. 5B, in a case in which the first transistor T1 is an N-type transistor, the source region SA1 of the first transistor T1 may be electrically connected to the anode of the light-emitting element ED, and the drain region DRA1 of the first transistor T1 may be electrically connected to the first power line PL1.

However, the present disclosure is not limited thereto, and as illustrated in FIG. 5C, in a case in which a first transistor T1 is a P-type transistor, a third transistor T3 for controlling a light emission may be additionally disposed between the source region SA1 of the first transistor T1 and the first power line PL1. In addition, in some embodiments, in a case in which the first transistor T1 is an N-type transistor, a transistor for controlling a light emission may be additionally disposed between the source region SA1 of the first transistor T1 and the anode of the light-emitting element ED.

According to an embodiment of the present disclosure, in a case in which the first transistor T1 is a P-type transistor, the source region SA1 of the first transistor T1 and the first power line PL1 may be directly connected to each other without an additional transistor therebetween, or only a transistor (e.g., the third transistor T3 of FIG. 5C) For controlling a light emission may be disposed and a transistor capable of serving as a resistance may not be disposed between the source region SA1 of the first transistor T1 and the first power line PL1. Likewise, in a case in which the first transistor T1 is an N-type transistor, the source region SA1 of the first transistor T1 and the anode of the light-emitting element ED may be directly connected to each other without an additional transistor therebetween, or only a transistor for controlling a light emission may be disposed and a transistor capable of serving as a resistance may not be disposed between the source region SA1 of the first transistor T1 and the anode of the light-emitting element ED. Accordingly, the display device DD (e.g., see FIG. 4) in which the number of transistors may be reduced may be provided.

The second transistor T2 is connected between the j-th data line DLj and the first node N1, and receives the i-th write scan signal Gwi. The second transistor T2 may be referred to as a switching transistor. The second transistor T2 may include a first electrode connected to the j-th data line DLj, a second electrode connected to the first node N1, and a gate electrode connected to the i-th write scan line GWLi. The second transistor T2 may be turned on by the i-th write scan signal GWi, which is received through the i-th write scan line GWLi, and may transmit, to the first node N1, the j-th data signal DSj transmitted from the j-th data line DLj.

The capacitor Cst may be connected between the first power line PL1 that provides the first driving voltage ELVDD and the first node N1. The capacitor Cst may include a first electrode connected to the first power line PL1, and a second electrode connected to the first node N1. The capacitor Cst may store a voltage difference between the first power line PL1 and the first node N1.

FIG. 5C is a circuit diagram of a pixel according to an embodiment of the present disclosure.

FIG. 5C illustrates, as an example, a pixel PXc including a pixel circuit PXCc, and a light-emitting element ED electrically connected to the pixel circuit PXCc. In the present embodiment, the pixel circuit PXCc may include four transistors (e.g., first to fourth transistors T1, T2, T3, and T4) and three capacitors (e.g., first to third capacitors C1, C2, and C3). Each of the first to fourth transistors T1 to T4 may be a transistor having a LTPS semiconductor layer. As an example, some of the first to fourth transistors T1 to T4 may be P-type transistors, and the others may be N-type transistors. For example, among the first to fourth transistors T1 to T4, the first to third transistors T1 to T3 may be P-type transistors, and the fourth transistor T4 may be an N-type transistor including an oxide semiconductor as a semiconductor layer. As another example, all of the first to fourth transistors T1 to T4 may be P-type transistors, or all of the first to fourth transistors T1 to T4 may be N-type transistors.

The first transistor T1 is connected between a first power line PL1 that receives a first driving voltage ELVDD and an anode of the light-emitting element ED. The first transistor T1 may be referred to as a driving transistor. The first transistor T1 may include a first electrode, a second electrode, and a gate electrode. The gate electrode may be connected to a first node N1, the first electrode may be connected to a second node N2, and the second electrode may be connected to the anode of the light-emitting element ED. The first electrode may be referred to as a source of the first transistor T1, and the second electrode may be referred to as a drain of the first transistor T1. According to a switching operation of the second transistor T2, the first transistor T1 may receive a j-th data signal DSj transmitted by a j-th data line DLj, and may supply a driving current Id to the light-emitting element ED.

The second transistor T2 is connected between the j-th data line DLj and the first node N1, and receives an i-th write scan signal GWi. The second transistor T2 may be referred to as a switching transistor. The second transistor T2 may include a first electrode connected to the j-th data line DLj, a second electrode connected to the first node N1, and a gate electrode connected to an i-th write scan line GWLi. The second transistor T2 may be turned on by the i-th write scan signal GWi received through the i-th write scan line GWLi, and may transmit, to the first node N1, the j-th data signal DSj transmitted from the j-th data line DLj.

The third transistor T3 is connected between the first power line PL1 and the second node N2, and receives an i-th light emission control signal EMi. The third transistor T3 may be turned on according to the i-th light emission control signal EMi, which is received through a light emission control line EMLi. The first driving voltage ELVDD applied through the turned-on third transistor T3 may be transmitted to the light-emitting element ED through the first transistor T1.

The fourth transistor T4 may be connected between a first voltage line VL1 that provides an initialization voltage VINT and the anode of the light-emitting element ED, and may receive an i-th reset scan signal GRi. The fourth transistor T4 may be turned on by the i-th reset scan signal GRi, which is received through an i-th reset scan line GRLi, and may transmit the initialization voltage VINT to the anode of the light-emitting element ED.

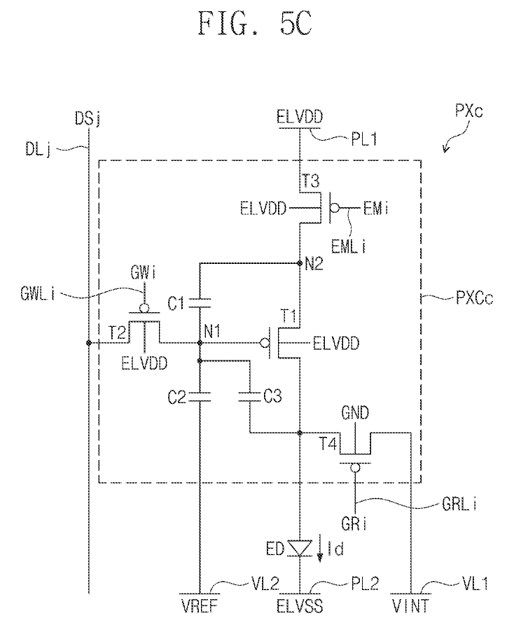

As an example, the first to fourth transistors T1 to T4 may each further include a third electrode. The third electrode of each of the first to fourth transistors T1 to T4 may be connected to a substrate (e.g., a semiconductor substrate SS of FIG. 6), so that the substrate may have a constant or substantially constant voltage. As illustrated in FIG. 5C, the third electrode of each of the first to third transistors T1 to T3 may receive the first driving voltage ELVDD, and the third electrode of the fourth transistor T4 may receive a ground voltage GND.

The first capacitor C1 may be connected between the first node N1 and the second node N2. The first capacitor C1 may store a voltage difference between the first node N1 and the second node N2.

The second capacitor C2 may be connected between the first node N1 and a second voltage line VL2 that provides a reference voltage VREF. The second capacitor C2 may store a voltage difference between the first node N1 and the second voltage line VL2.

The third capacitor C3 may be connected between the first node N1 and the first voltage line VL1 that provides the initialization voltage VINT. The third capacitor C3 may store a voltage difference between the first node N1 and the first voltage line VL1.

However, the present disclosure is not limited thereto. In addition to the configurations of the pixel circuits PXCa, PXCb, and PXCc described above with reference to FIGS. 5A, 5B, and 5C, the number of transistors or the number of capacitors may be variously modified according to a desired design of the pixel circuit.

FIG. 6 is a block diagram of a first transistor according to an embodiment of the present disclosure. FIG. 7 is a block diagram of a second transistor according to an embodiment of the present disclosure.

Referring to FIG. 6, a first transistor T1 may be formed in and on a semiconductor substrate SS. The first transistor T1 may include a channel region CHA1, a source region SA1 adjacent to a first side of the channel region CHA1, a drain region DRA1 adjacent to a second side of the channel region CHA1, a gate insulating layer GIN1 disposed on the channel region CHA1, and a gate GA1 disposed on the gate insulating layer GIN1.

The semiconductor substrate SS may be a silicon substrate, a germanium substrate, or a silicon-germanium substrate. At least a portion of the semiconductor substrate SS may be doped with a first-type impurity. Each of the source region SA1 and the drain region DRA1 may be a region doped with a second-type impurity. The second-type impurity may be different from the first-type impurity. For example, in a case in which the first-type impurity is a p-type impurity, the second-type impurity may be an n-type impurity. As another example, in a case in which the first-type impurity is an n-type impurity, the second-type impurity may be a p-type impurity.

The gate GA1 of the first transistor T1 may be disposed in correspondence to the source region SA1 and the drain region DRA1. The source region SA1 and the drain region DRA1 of the first transistor T1 may be formed to be asymmetrical with each other with respect to the gate GA1. In other words, the source region SA1 of the first transistor T1 may be spaced apart from the gate GA1 in a plan view, and the drain region DRA1 of the first transistor T1 may be adjacent to the gate GA1 in a plan view.

A region between the source region SA1 and the drain region DRA1 may be referred to as the channel region CHA1. When a voltage is applied to the gate GA1, the channel region CHA1 may be formed at the semiconductor substrate SS due to a field effect, and a current may flow through the channel region CHA1. In the present embodiment, when a voltage is applied to the gate GA1 of the first transistor T1, a current may flow from the source region SA1 to the drain region DRA1 through the channel region CHA1.

The channel region CHA1 may include a first channel region CHA1-1 and a second channel region CHA1-2. The first channel region CHA1-1 may be a region of the channel region CHA1 overlapping with the gate GA1 in a plan view, and the second channel region CHA1-2 may be a region of the channel region CHA1 not overlapping with the gate GA1 in a plan view. The drain region DRA1, may be adjacent to the first channel region CHA1-1 and may overlap with the gate GA1 in a plan view. The source region SA1 may be adjacent to the second channel region CHA1-2, and may be spaced apart from the gate GA1 in a plan view.

The second channel region CHA1-2 may not overlap with the gate GA1 in a plan view, and thus, when a voltage is applied to the gate GA1 of the first transistor T1 and a current flows from the source region SA1 to the drain region DRA1, carriers (e.g., holes or charges) may be less accumulated in the second channel region CHA1-2 than in the first channel region CHA1-1. Thus, the second channel region CHA1-2 may have a higher resistance than that of the first channel region CHA1-1. In other words, the second channel region CHA1-2 may operate as a resistance. Thus, the source region SA1 may be spaced apart from the gate GA1 in a plan view, and may operate as if a resistance (e.g., a predetermined resistance) is connected to the source region SA1 of the first transistor T1. When a transistor is formed on the semiconductor substrate SS, a driving current may be significantly changed by even a small change in a gate voltage. Thus, a difference in a luminance of a pixel may be significantly generated between adjacent pixels by even a small change in a voltage, and thus, a luminance may not be uniform. According to the present embodiment, because a resistance may be added to the source region SA1 of the first transistor T1, a source voltage may be affected when a driving current changes, and a change in current may be slower through a feedback effect. Thus, a drastic change in current may be prevented or substantially prevented, thereby providing a display device having a uniform luminance.

Referring to FIG. 7, a second transistor T2 may be formed in and on a semiconductor substrate SS. The second transistor T2 may include a channel region CHA2, a source region SA2 adjacent to a first side of the channel region CHA2, a drain region DRA2 adjacent to a second side of the channel region CHA2, a gate insulating layer GIN2 disposed on the channel region CHA2, and a gate GA2 disposed on the gate insulating layer GIN2.

The gate GA2 of the second transistor T2 may be disposed in correspondence to the source region SA2 and the drain region DRA2. The source region SA2 and the drain region DRA2 of the second transistor T2 may be formed to be symmetrical with each other with respect to the gate GA2. In other words, the source region SA2 of the second transistor T2 may be adjacent to the gate GA2 in a plan view, and the drain region DRA2 of the second transistor T 2may be adjacent to the gate GA2 in a plan view.

The source region SA2 may include a first low-concentration impurity region LDD1 adjacent to the channel region CHA2, and the drain region DRA2 may include a second low-concentration impurity region LDD2 adjacent to the channel region CHA2. The first low-concentration impurity region LDD1 may be a region having a lower impurity concentration in the source region SA2. The second low-concentration impurity region LDD2 may be a region having a lower impurity concentration in the drain region DRA2. A distance between the source region SA2 and the drain region DRA2 may be increased due to the first low-concentration impurity region LDD1 and the second low-concentration impurity region LDD2. Thus, because a length of the channel region CHA2 of the second transistor T2 may be increased, a punch-through and a hot carrier phenomena due to a shorter channel may be prevented or substantially prevented.

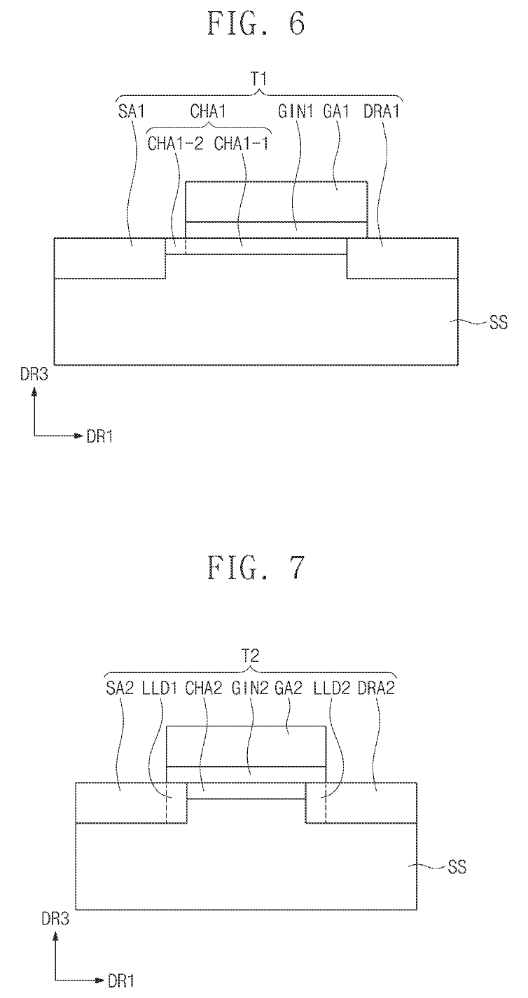

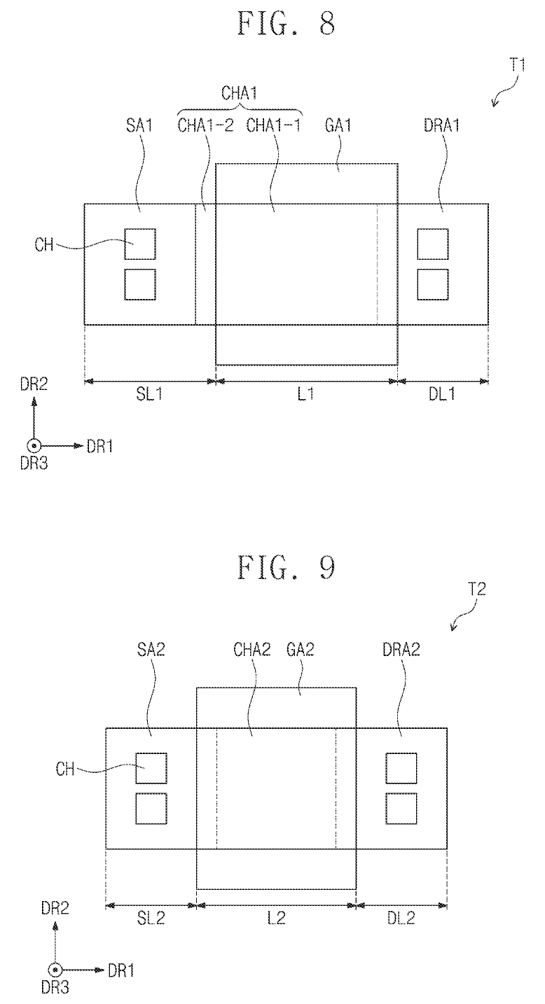

FIG. 8 is a plan view of a first transistor according to an embodiment of the present disclosure. FIG. 9 is a plan view of a second transistor according to an embodiment of the present disclosure.

Referring to FIGS. 8 and 9, a first transistor T1 and a second transistor T2 may include channel regions CHA1 and CHA2, respectively, between source regions SA1 and SA2 and drain regions DRA1 and DRA2. The channel region CHA1 of the first transistor T1 may include a first channel region CHA1-1 overlapping with a gate GA1, and a second channel region CHA1-2 not overlapping with the gate GA1. The channel region CHA2 of the second transistor T2 may entirely overlap with a gate GA2. The source regions SA1 and SA2 and the drain regions DRA1 and DRA2 of the first and second transistors T1 and T2 may be electrically connected to the light-emitting element ED (e.g., see FIG. 5A) thereabove through contact holes CH.

A first source length SL1 and a first drain length DL1 may be defined in the first transistor T1. The first source length SL1 is a sum of a length in the first direction DR1 of the source region SA1 and a length of the second channel region CHA1-2. The first drain length DL1 is a length in the first direction DR1 of a region of the drain region DRA1 not overlapping with the gate GA1. Because the first source length SL1 includes the length of the second channel region CHA1-2, the first source length SL1 may be greater than the first drain length DL1.

A second source length SL2 and a second drain length DL2 may be defined in the second transistor T2. The second source length SL2 is a length in the first direction DR1 of a region of the source region SA2 not overlapping with the gate GA2. The second drain length DL2 is a length in the first direction DR1 of a region of the drain region DRA2 not overlapping with the gate GA2. The second source length SL2 may be the same or substantially the same as the second drain length DL2. As an example, the first drain length DL1, the second drain length DL2, and the second source length SL2 may be the same or substantially the same as each other.

The gate GA1 of the first transistor T1 may have a first length L1, and the gate GA2 of the second transistor T2 may have a second length L2. As an example, the first length L1 may be greater than the second length L2. In other words, a length of the channel region CHA1 of the first transistor T1 may be greater than a length of the channel region CHA2 of the second transistor T2. As the length of the channel region CHA1 is greater, when a voltage is applied to the gate GA1, a field effect may be distributed in the longer channel region CHA1. Thus, a drastic change in a driving current caused by even a small change in a voltage may be prevented or substantially prevented, thereby providing a display device having a uniform luminance.

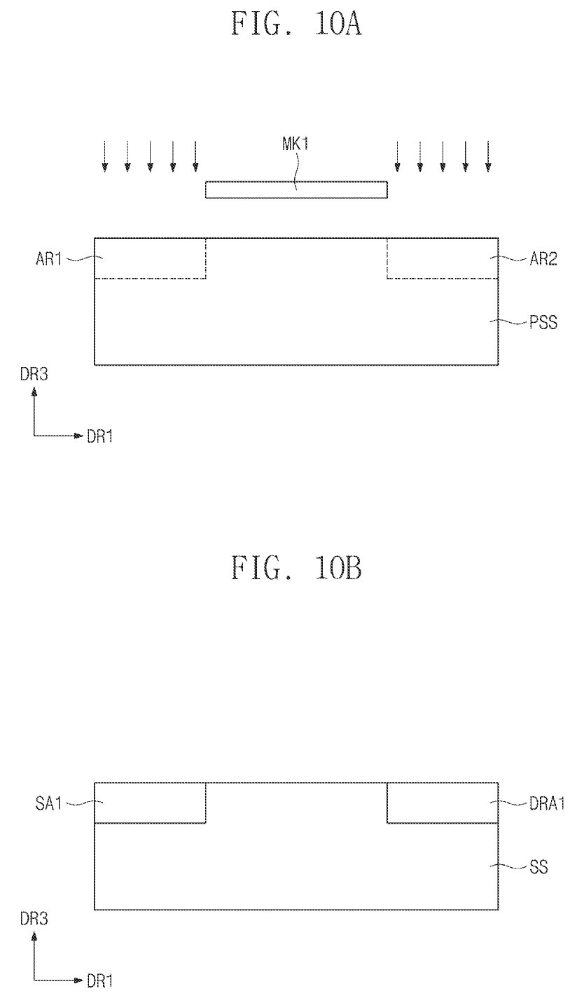

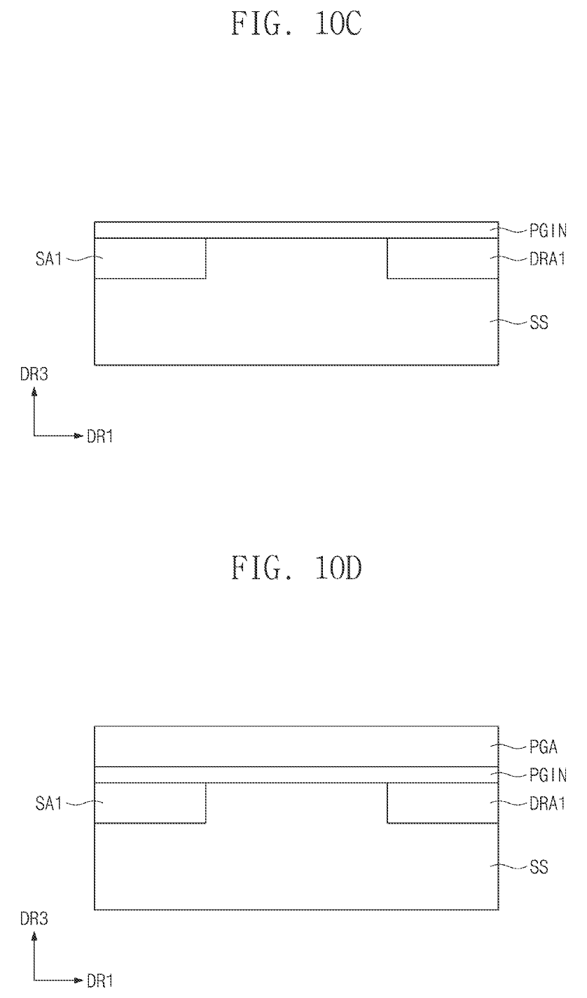

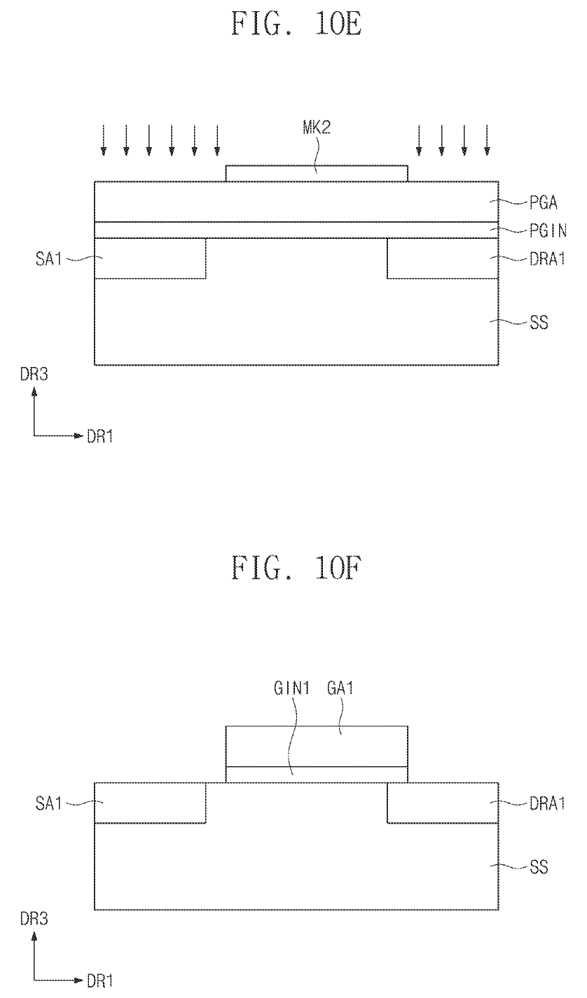

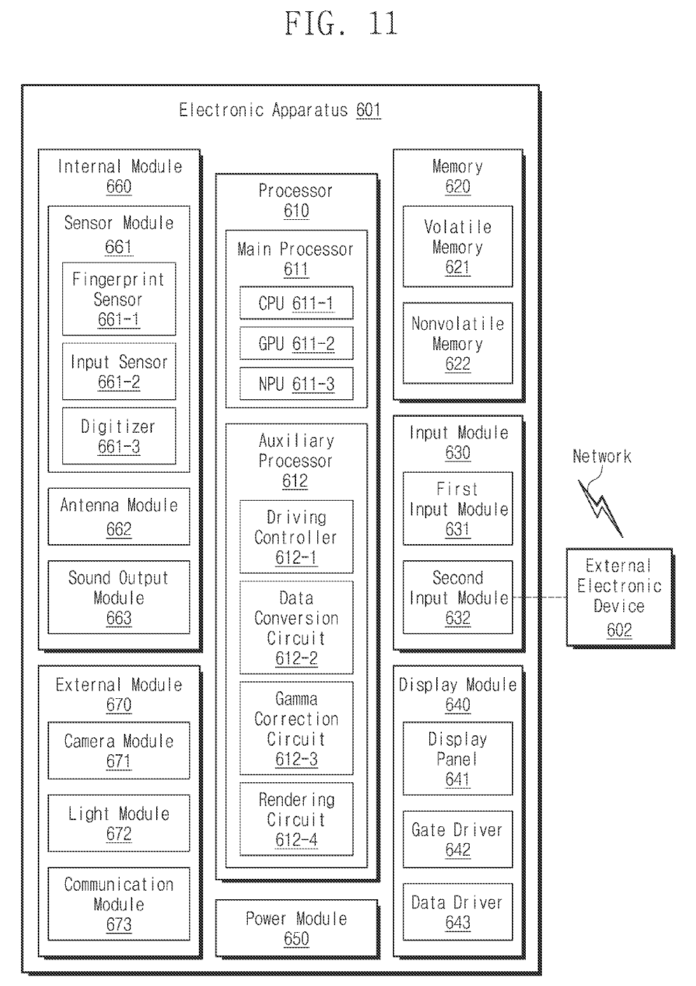

FIGS. 10A through 10F are cross-sectional views illustrating a method of manufacturing a first transistor according to an embodiment of the present disclosure.

Referring to FIG. 10A, a preliminary semiconductor substrate PSS doped with a first-type impurity may be prepared. The entire region of the preliminary semiconductor substrate (PSS) may be doped with the first-type impurity. The preliminary semiconductor substrate PSS may include a first doped region AR1 and a second doped region AR2. The preliminary semiconductor substrate PSS may be a silicon substrate, a germanium substrate, or a silicon-germanium substrate. The first doped region AR1 and the second doped region AR2 may be doped with a second impurity by using a first mask MK1. The first mask MK1 may not overlap with the first doped region AR1 and the second doped region AR2 in a plan view.

Referring to FIG. 10B, a semiconductor substrate SS may include a source region SA1 and a drain region DRA1. The source region SA1 and the drain region DRA1 may be formed by doping the first doped region AR1 and the second doped region AR2 of the preliminary semiconductor substrate PSS, respectively. The source region SA1 and the drain region DRA1 may be doped with an impurity different from that of the preliminary semiconductor substrate PSS. In other words, the semiconductor substrate SS may be provided by forming the source region SA1 and the drain region DRA1 by doping the first doped region AR1 and the second doped region AR2 in the preliminary semiconductor substrate PSS with a second impurity, and doping the remaining region of the preliminary semiconductor substrate PSS with a first-type impurity. The source region SA1 and the drain region DRA1 may be formed to be spaced apart from each other in a plan view.

Referring to FIG. 10C, a preliminary gate insulating layer PGIN may be formed on an upper surface of the semiconductor substrate SS. The preliminary gate insulating layer PGIN may include silicon dioxide (SiO₂), silicon nitride (Si₃N₄), aluminum oxide (Al₂O₃), and/or titanium dioxide (TiO₂).

Referring to FIG. 10D, a preliminary gate PGA may be formed on an upper surface of the preliminary gate insulating layer PGIN. The preliminary gate PGA may include polysilicon, titanium nitride (TiN), tungsten (W), molybdenum (Mo), and/or aluminum (Al).

Referring to FIG. 10E, the preliminary gate insulating layer PGIN and the preliminary gate PGA may be etched using a second mask MK2. The second mask MK2 may be disposed to overlap with a gate insulating layer GIN1 and a gate GA1 to form the gate insulating layer GIN1 and the gate GA1 illustrated in FIG. 10F. The second mask MK2 may be spaced apart from the source region SA1 in a plan view, and may partially overlap with the drain region DRA1 in a plan view. However, the present disclosure is not limited thereto, and the second mask MK2 may not overlap with the drain region DRA1 in a plan view. As an example, the first mask MK1 may overlap with the second channel region CHA1-2 (e.g., see FIG. 6), and the second mask MK2 may not overlap with the second channel region CHA1-2. Accordingly, in a process of forming the first transistor T1, the channel region CHA1 (e.g., see FIG. 6) Between the source region SA1 and the drain region DRA1 may be defined by the first mask MK1, and the second channel region CHA1-2 of the channel region CHA1 not overlapping with the gate GA1 may be defined by the second mask MK2.

Referring to FIG. 10F, the gate insulating layer GIN1 and the gate GA1 may be formed by etching the preliminary gate insulating layer PGIN and the preliminary gate PGA. The gate insulating layer GIN1 and the gate GA1 may be spaced apart from the source region SA1 in a plan view, and may partially overlap with the drain region DRA1 in a plan view. However, the present disclosure is not limited thereto, and the gate insulating layer GIN1 and the gate GA1 may not overlap with the drain region DRA1 in a plan view.

FIG. 11 is a block diagram of an electronic apparatus according to an embodiment of the present disclosure.

Referring to FIG. 11, an electronic apparatus 601 outputs a variety of information through a display module 640 in an operating system. When a processor 610 executes an application stored in a memory 620, the display module 640 provides application information to a user through a display panel 641.

The processor 610 obtains an external input through an input module 630 or a sensor module 661, and executes an application corresponding to the external input. For example, when a user selects a camera icon displayed on the display panel 641, the processor 610 obtains a user input through an input sensor 661-2 and activates a camera module 671. The processor 610 transmits, to the display module 640, image data corresponding to a captured image obtained through the camera module 671. The display module 640 may display an image corresponding to the captured image through the display panel 641.

As another example, when personal information authentication is executed in the display module 640, a fingerprint sensor 661-1 obtains input fingerprint information as input data. The processor 610 compares the input data obtained through the fingerprint sensor 661-1 with authentication data stored in the memory 620, and executes an application according to a comparison result. The display module 640 may display information executed according to a logic of the application through the display panel 641.

As another example, when a music streaming icon displayed on the display module 640 is selected, the processor 610 obtains a user input through the input sensor 661-2 and activates a music streaming application stored in the memory 620. When a music execution command is input in the music streaming application, the processor 610 activates a sound output module 663, and provides, to a user, sound information corresponding to the music execution command.

An operation of the electronic apparatus 601 is briefly described above. Hereinafter, a configuration of the electronic apparatus 601 is described in more detail. Some components of the electronic apparatus 601 to be described in more detail below may be integrated with each other and provided as one component, and one component may be separated into two or more components.

Referring to FIG. 11, the electronic apparatus 601 may communicate with an external electronic apparatus 602 via a network (e.g., a short-range wireless communication network or a long-range wireless communication network). According to an embodiment, the electronic apparatus 601 may include the processor 610, the memory 620, the input module 630, the display module 640, a power module 650, an internal module 660, and an external module 670. According to an embodiment, in the electronic apparatus 601, at least one of the components described above may be omitted as needed or desired, or one or more other components may be added. According to an embodiment, some of the components (e.g., the sensor module 661, an antenna module 662, or the sound output module 663) may be integrated into another component (e.g., the display module 640).

The processor 610 may execute software to control at least one other component (e.g., hardware or software component) of the electronic apparatus 601 connected to the processor 610, and may perform various data processing or operations. According to an embodiment, as at least part of the data processing or operations, the processor 610 may store data or a command received from another component (e.g., the input module 630, the sensor module 661, or a communication module 673) in a volatile memory 621, and may process the data or command stored in the volatile memory 621, and thus, result data may be stored in a nonvolatile memory 622.

The processor 610 may include a main processor 611 and an auxiliary processor 612. The main processor 611 may include one or more among a central processing unit (CPU) 611-1 and/or an application processor (AP). The main processor 611 may further include one or more among a graphic processing unit (GPU) 611-2, a communication processor (CP), and/or an image signal processor (ISP). The main processor 611 may further include a neural processing unit (NPU) 611-3. The neural processing unit may be a processor that is specialized for processing an artificial intelligence model, and the artificial intelligence model may be generated through machine learning. The artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or a combination of two or more of the above, but the present disclosure is not limited thereto. The artificial intelligence model may include a software structure in addition to or instead of a hardware structure. At least two among the processing units and/or processors described above may be implemented as one integrated component (e.g., a single chip), or may each be implemented as an independent component (e.g., a plurality of chips).

The auxiliary processor 612 may include a driving controller 612-1. The driving controller 612-1 may include an interface conversion circuit and a timing control circuit. The driving controller 612-1 receives an image signal from the main processor 611, converts a data format of the image signal to comply with specifications of an interface with the display module 640, and outputs image data. The driving controller 612-1 may output various control signals used for driving the display module 640. Because a configuration of the driving controller 612-1 may be the same or substantially the same as (or similar to) that of the driving controller 100 described above with reference to FIG. 2, redundant description thereof may not be repeated.

The auxiliary processor 612 may further include a data conversion circuit 612-2, a gamma correction circuit 612-3, a rendering circuit 612-4, and/or the like. The data conversion circuit 612-2 may receive image data from the driving controller 612-1, and may compensate for the image data so that an image is displayed at a desired luminance according to characteristics of the electronic apparatus 601, a user’s setting, or the like, or may convert the image data to reduce a power consumption, to compensate for an afterimage, or the like. The gamma correction circuit 612-3 may convert image data, a gamma reference voltage, or the like so that an image displayed on the electronic apparatus 601 has a desired gamma characteristic. The rendering circuit 612-4 may receive image data from the driving controller 612-1, and may render the image data in consideration of a pixel arrangement of the display panel 641 applied to the electronic apparatus 601 and/or the like. At least one of the data conversion circuit 612-2, the gamma correction circuit 612-3, or the rendering circuit 612-4 may be integrated to another component (e.g., the main processor 611 or the controller 612-1). At least one of the data conversion circuit 612-2, the gamma correction circuit 612-3, or the rendering circuit 612-4 may be integrated to a data driver 643 to be described in more detail below.

The memory 620 may store various pieces of data used by at least one component (e.g., the processor 610 or the sensor module 661) of the electronic apparatus 601, and may output data or input data about a command related thereto. The memory 620 may include at least one of the volatile memory 621 or the nonvolatile memory 622.

The input module 630 may receive data or a command to be used in a component (e.g., the processor 610, the sensor module 661, or the sound output module 663) of the electronic apparatus 601 from the outside (e.g., a user or the external electronic apparatus 602) of the electronic apparatus 601.

The input module 630 may include a first input module 631 to which a command or data is input from a user, and a second input module 632 to which a command or data is input from the external electronic apparatus 602. The first input module 631 may include a microphone, a mouse, a keyboard, a key (e.g., a button), or a pen (e.g., a passive pen or an active pen). The second input module 632 may support a designated protocol for wired or wireless connection to the external electronic apparatus 602. According to an embodiment, the second input module 632 may include a high definition multimedia interface (HDMI), a universal serial bus (USB) interface, an SD card interface, or an audio interface. The second input module 632 may include a connector for a physical connection to the external electronic apparatus 602, for example, such as an HDMI connector, a USB connector, an SD card connector, or an audio connector (e.g., a headphone connector).

The display module 640 visually provides information to a user. The display module 640 may include the display panel 641, a gate driver 642, and a data driver 643. The display module 640 may further include a chassis, a bracket, and a window for protecting the display panel 641. The display module 640 may further include a light emission driver, a voltage generator, and the like. The voltage generator may output various voltages (e.g., the first and second driving voltages ELVDD and ELVSS of FIG. 4) used for driving the display panel 641. Because a configuration of the display panel 641, the gate driver 642, the data driver 643, and the voltage generator is the same or substantially the same as (or similar to) that of the display panel DP, the gate driver 300, and the data driver 200 described above with reference to FIG. 4, redundant description thereof may not be repeated.

The power module 650 supplies power to a component of the electronic apparatus 601. The power module 650 may include a battery that charges a power voltage. The battery may include a non-rechargeable primary cell, a rechargeable secondary cell, or a fuel cell. The power module 650 may include a power management integrated circuit (PMIC). The PMIC supplies optimized power to each of the modules described above and a module to be described in more detail below. The power module 650 may include a wireless power transmission/reception member electrically connected to the battery. The wireless power transmission/reception member may include a plurality of antenna radiators in a coil form.

The electronic apparatus 601 may further include the internal module 660 and the external module 670. The internal module 660 may include the sensor module 661, the antenna module 662, and the sound output module 663. The external module 670 may include the camera module 671, a light module 672, and the communication module 673.

The sensor module 661 may sense an input from a user’s body or an input from a pen of the first input module 631, and may generate a data value or an electrical signal corresponding to the input. The sensor module 661 may include at least one of the fingerprint sensor 661-1, the input sensor 661-2, or a digitizer 661-3.

The fingerprint sensor 661-1 may generate a data value corresponding to a user’s fingerprint. The fingerprint sensor 661-1 may include any one of an optical fingerprint sensor and/or a capacitive fingerprint sensor.

The input sensor 661-2 may generate a data value corresponding to coordinate information about an input from a user’s body or an input from a pen. The input sensor 661-2 generates the amount of change in a capacitance due to an input as a data value. The input sensor 661-2 may sense an input from a passive pen or transmit/receive data to/from an active pen.

The input sensor 661-2 may measure a bio signal such as blood pressure, water, or body fat. For example, when a user is in contact with a sensor layer or a sensing panel with a part of a user’s body and does not move for a certain amount of time, on the basis of a change in an electric field caused by the part of the user’s body, the input sensor 661-2 may sense a bio signal and output information desired by the user to the display module 640.

The digitizer 661-3 may generate a data value corresponding to coordinate information about an input from a pen. The digitizer 661-3 generates the amount of electromagnetic change due to an input as a data value. The digitizer 661-3 may sense an input from a passive pen or transmit/receive data to/from an active pen.

At least one of the fingerprint sensor 661-1, the input sensor 661-2, or the digitizer 661-3 may be implemented as a sensor layer formed on the display panel 641 through a continuous process. The fingerprint sensor 661-1, the input sensor 661-2, and the digitizer 661-3 may be disposed above the display panel 641, and any one of the fingerprint sensor 661-1, the input sensor 661-2, and/or the digitizer 661-3, for example, such as the digitizer 661-3, may be disposed below the display panel 641.

At least two of the fingerprint sensor 661-1, the input sensor 661-2, and/or the digitizer 661-3 may be formed to be integrated to one sensing panel through the same process. In a case in which at least two of the fingerprint sensor 661-1, the input sensor 661-2, and/or the digitizer 661-3 are integrated to one sensing panel, the sensing panel may be disposed between the display panel 641 and a window disposed above the display panel 641. According to an embodiment, the sensing panel may be disposed on the window, and a position of the sensing panel is not particularly limited.

At least one of the fingerprint sensor 661-1, the input sensor 661-2, or the digitizer 661-3 may be built in the display panel 641. In other words, at least one of the fingerprint sensor 661-1, the input sensor 661-2, or the digitizer 661-3 may be concurrently (e.g., simultaneously or substantially simultaneously) formed through a process of forming elements (e.g., a light-emitting element, a transistor, and/or the like) included in the display panel 641.

In addition, the sensor module 661 may generate a data value or an electrical signal corresponding to an internal state or an external state of the electronic apparatus 601. The sensor module 661 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 662 may include one or more antennas for transmitting or receiving a signal or power to or from the outside. According to an embodiment, the communication module 673 may transmit or receive a signal to or from an external electronic apparatus through an antenna suitable for a communication method. An antenna pattern of the antenna module 662 may be integrated to one component (e.g., the display panel 641) of the display module 640, the input sensor 661-2, or the like.

The sound output module 663 may be a device for outputting a sound signal to the outside of the electronic apparatus 601, and may include, for example, a speaker used for general purposes such as playing multimedia or playing a recording, and a receiver used only for receiving a call. According to an embodiment, the receiver may be formed integrally with or separately from the speaker. A sound output pattern of the sound output module 663 may be integrated to the display module 640.

The camera module 671 may capture a still image and a moving image. According to an embodiment, the camera module 671 may include one or more lenses, an image sensor, or an image signal processor. The camera module 671 may further include an infrared camera capable of measuring a presence/absence of a user, a position of a user, a gaze of a user, and/or the like.

The light module 672 may provide light. The light module 672 may include a light-emitting diode or a xenon lamp. The light module 672 may operate in association with the camera module 671 or may operate independently.

The communication module 673 may support establishing a wired or wireless communication channel between the electronic apparatus 601 and the external electronic apparatus 602, and performing communication via the established communication channel. The communication module 673 may include any one or both of a wireless communication module, such as a cellular communication module, a short-range wireless communication module, or a global navigation satellite system (GNSS) communication module, and a wired communication module, such as a local area network (LAN) communication module or a power line communication module. The communication module 673 may communicate with the external electronic apparatus 602 via a short-range communication network such as Bluetooth, Wi-Fi direct, or infrared data association (IrDA), or a long-range communication network such as a cellular network, internet, or a computer network (e.g., LAN or WAN). The various kinds of the communication modules 673 described above may be implemented as one chip, or may be each implemented as a separate chip.

The input module 630, the sensor module 661, the camera module 671, and the like may be used for controlling an operation of the display module 640 in association with the processor 610.

The processor 610 outputs a command or data to the display module 640, the sound output module 663, the camera module 671, or the light module 672 on the basis of input data received from the input module 630. For example, the processor 610 may generate image data in correspondence to input data applied through a mouse, an active pen, or the like, and may output the image data to the display module 640, or may generate command data in correspondence to input data, and may output the command data to the camera module 671 or the light module 672. When input data is not received from the input module 630 for a certain amount of time, the processor 610 may change an operation mode of the electronic apparatus 601 to a low power mode or a sleep mode, thereby reducing a power consumption of the electronic apparatus 601.

The processor 610 outputs a command or data to the display module 640, the sound output module 663, the camera module 671, or the light module 672 on the basis of sensing data received from the sensor module 661. For example, the processor 610 may compare authentication data applied by the fingerprint sensor 661-1 with authentication data stored in the memory 620, and then execute an application according to a comparison result. The processor 610 may execute a command or output corresponding image data to the display module 640 on the basis of sensing data that is sensed by the input sensor 661-2 or the digitizer 661-3. In a case in which a temperature sensor is included in the sensor module 661, the processor 610 may receive temperature data about a measured temperature from the sensor module 661, and may further perform a luminance correction on image data or the like on the basis of the temperature data.

The processor 610 may receive measurement data about a presence/absence of a user, a position of a user, a gaze of a user, and/or the like from the camera module 671. The processor 610 may further perform a luminance correction on image data and the like on the basis of the measurement data. For example, the processor 610 determines a presence/absence of a user through an input from the camera module 671, and then may output image data of which a luminance is corrected through the data conversion circuit 612-2 or the gamma correction circuit 612-3 to the display module 640.

Some of the above components may be connected to each other through a communication method between peripheral devices, for example, such as a bus, a general purpose input/output (GPIO), a serial peripheral interface (SPI), a mobile industry processor interface (MIPI), or an ultra path interconnect (UPI) link, and may exchange a signal (e.g., command or data). The processor 610 may communicate with the display module 640 through a mutually agreed interface, and for example, may use any one of the communication methods described above without being limited to the communication methods described above.

The electronic apparatus 601 according to various embodiments may be devices in various suitable forms. For example, the electronic apparatus 601 may include at least one among a portable communication apparatus (e.g., a smartphone), a computer apparatus, a portable multimedia apparatus, a portable medical apparatus, a camera, a wearable apparatus, and/or a home appliance. The electronic apparatus 601 is not limited to the apparatuses described above.

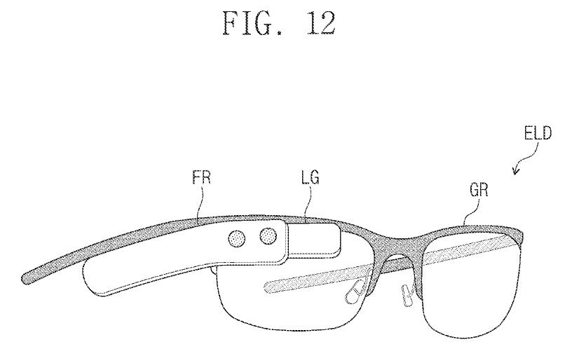

FIG. 12 is an exploded perspective view of an electronic apparatus according to an embodiment of the present disclosure.

FIG. 12 illustrates augmented reality (AR) glasses as an example of a wearable apparatus. An electronic apparatus ELD may include glasses GR, and a frame FR mounted on the glasses GR. The frame FR may accommodate the display panel 641 described above with reference to FIG. 11, or may accommodate other modules described above with reference to FIG. 11. A light guide LG that guides an image generated at the display panel 641 may be mounted on the frame FR.

The glasses GR may be worn on a user’s head. In the present embodiment, because augmented reality (AR) glasses are described as an example of a wearable apparatus, a structure on which the frame FR is mounted is described as glasses. The structure may vary according to a kind of a wearable apparatus. In addition, the structure may be omitted according to a kind of the electronic apparatus ELD.

According to some embodiments of the present disclosure, a region that operates like a resistance may be added by arranging a gate and a source region of a driving transistor to be spaced apart from each other in a plan view. In a case in which a resistance is added to the source region of the driving transistor, a drastic change in driving current may be prevented or substantially prevented.

In addition, according to some embodiments of the present disclosure, a length of the gate of the driving transistor may be greater than a length of a gate of a switching transistor. In this case, a channel of the driving transistor may be formed to have a greater length, thereby preventing or substantially preventing a drastic change in a driving current.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.in more detail below

What is claimed is:

1. A display device comprising:
a semiconductor substrate; and
a plurality of pixels in and on the semiconductor substrate, each of the plurality of pixels comprising:
a light-emitting element;
a first transistor between a first power line and the light-emitting element; and
a second transistor between a data line and the first transistor,
wherein the first transistor comprises a channel region, a source region adjacent to a first side of the channel region, a drain region adjacent to a second side of the channel region, and a gate on the channel region, and
wherein the channel region of the first transistor comprises a first channel region overlapping with the gate of the first transistor in a plan view, and a second channel region not overlapping with the gate of the first transistor in a plan view.

2. The display device of claim 1, wherein the first transistor comprises a PMOS transistor.

3. The display device of claim 2, wherein the source region of the first transistor is electrically connected to the first power line.

4. The display device of claim 1, wherein the first transistor comprises an NMOS transistor.

5. The display device of claim 4, wherein the source region of the first transistor is electrically connected to the light-emitting element.

6. The display device of claim 1, wherein at least a portion of the semiconductor substrate is doped with a first impurity, and
wherein the source region of the first transistor and the drain region of the first transistor are doped with a second impurity different from the first impurity.

7. The display device of claim 1, wherein the gate and the source region of the first transistor are spaced from each other in a plan view, and the gate and the drain region of the first transistor are adjacent to each other in a plan view.

8. The display device of claim 1, wherein the second transistor comprises a channel region, a source region adjacent to a first side of the channel region, a drain region adjacent to a second side of the channel region, and a gate on the channel region, and
wherein the channel region of the second transistor entirely overlaps with the gate of the second transistor in a plan view.

9. The display device of claim 8, wherein the gate and the source region of the second transistor are adjacent to each other in a plan view, and the gate and the drain region of the second transistor are adjacent to each other in a plan view.

10. The display device of claim 8, wherein a first source length and a first drain length of the first transistor are different from each other, and
wherein a second source length and a second drain length of the second transistor are same as each other.

11. The display device of claim 8, wherein a length of the gate of the first transistor is greater than a length of the gate of the second transistor.

12. The display device of claim 1, wherein a resistance of the second channel region is higher than a resistance of the first channel region.

13. A method of manufacturing a display device, the method comprising:
preparing a preliminary semiconductor substrate doped with a first impurity;
providing a semiconductor substrate by forming a source region and a drain region by doping first and second doped regions of the preliminary semiconductor substrate with a second impurity by using a first mask;
forming a preliminary gate insulating layer on an upper surface of the semiconductor substrate;
forming a preliminary gate on an upper surface of the preliminary gate insulating layer; and
forming a gate insulating layer and a gate by etching the preliminary gate insulating layer and the preliminary gate by using a second mask,
wherein the display device comprises a first channel region overlapping with the gate in a plan view, and a second channel region not overlapping with the gate in a plan view between the source region and the drain region.

14. The method of claim 13, wherein the display device comprises a plurality of pixels disposed in and on the semiconductor substrate, each of the plurality of pixels comprising:
a light-emitting element;
a first transistor disposed between a first power line and the light-emitting element; and
a second transistor disposed between a data line and the first transistor, and
wherein the first transistor comprises the source region, the drain region, and the gate.

15. The method of claim 14, wherein the gate and the source region of the first transistor are spaced apart from each other in a plan view, and the gate and the drain region of the first transistor are adjacent to each other in a plan view.

16. The method of claim 14, wherein the first mask does not overlap with the source region and the drain region of the first transistor in a plan view.

17. The method of claim 14, wherein the second mask overlaps with the gate insulating layer and the gate of the first transistor in a plan view.

18. The method of claim 13, wherein the first mask overlaps with the second channel region in a plan view, and the second mask does not overlap with the second channel region in a plan view.

19. The method of claim 13, wherein a resistance of the second channel region is higher than a resistance of the first channel region.

20. An electronic apparatus comprising:
a display panel;
a frame accommodating the display panel; and
a structure on which the frame is mounted,
wherein the display panel comprises:
a semiconductor substrate; and
a plurality of pixels in and on the semiconductor substrate,
wherein each of the plurality of pixels comprises:
a light-emitting element;
a first transistor between a first power line and the light-emitting element; and
a second transistor between a data line and the first transistor,
wherein the first transistor comprises a channel region, a source region adjacent to a first side of the channel region, a drain region adjacent to a second side of the channel region, and a gate on the channel region, and
wherein the channel region of the first transistor comprises a first channel region overlapping with the gate of the first transistor in a plan view, and a second channel region not overlapping with the gate of the first transistor in a plan view.
